(19) United States
(12) Patent Application Publication
(10) Pub. No.: US 2003/0172338 A1
(43) Pub. Date: Sep. 11, 2003

(54) Transmission apparatus and transmission method with simplified rate conversion

(76) Inventors: Yoshikuni Miyata, Tokyo (JP); Hachiro Fujita, Tokyo (JP); Takahiko Nakamura, Tokyo (JP); Hideo Yoshida, Tokyo (JP)

Correspondence Address: BIRCH STEWART KOLASCH & BIRCH, PO BOX 747, FALLS CHURCH, VA, 22040-0747, US

(21) Appl. No.: 10/379,602

(22) Filed: Mar. 6, 2003

(30) Foreign Application Priority Data
Mar. 7, 2002 (JP) 2002-62514

(51) Int. Cl. H03M 13/00

(52) U.S. Cl. 714/758

(57) ABSTRACT

An RS encoding circuit encodes for error correction bits for information symbols in which information bits are assigned to low-order bits and dummy bits are assigned to high-order bits so as to generate bits for parity symbols such that the number of bits per information symbol is equal to the number of bits per parity symbol. A symbol conversion circuit subjects high-order bits for parity symbols to symbol conversion.

### BACKGROUND OF THE INVENTION

1. Field of the Invention

The present invention generally relates to a transmission apparatus and a transmission method using an M-ary quadrature amplitude modulation as a modulating scheme and using a multidimensional error correction codes for error correction.

2. Description of the Related Art

FIG. 4 shows a construction of a transmission apparatus according to the related art. FIGS. 5A and 5B show a construction of frames transmitted in a scheme in which M-ary quadrature amplitude modulation (QAM) is used for modulation and the Reed-Solomon code, a multidimensional block error correction code, is used for error correction. FIG. 5A shows an RS encoded frame RS encoded over a Galois field of GF(2⁷). FIG. 5B shows a transmission frame used when the RS encoded frame is transmitted using 128QAM.

Referring to FIGS. 5A and 5B, information bits are arranged by assigning 7 bits to a symbol so as to produce RS information bits 1. RS parity bits 2 are generated by subjecting the RS information bits 1 to RS encoding. The 128QAM transmission frame comprises frame synchronization bits 3.

Referring to FIG. 4, the transmission apparatus comprises a delay buffer 11 for temporarily holding the RS information bits 1, an RS encoding circuit 12 for subjecting the RS information bits 1 to RS encoding so as to generate the RS parity bits 2 of an arrangement of 7 bits per symbol, a 128 QAM transmission frame constructing circuit 13 for forming RS encoded bits by combining the RS information bits 1 and the RS parity bits 2 and by adding to the RS encoded bits extra bits for transmission control including the RS frame synchronization bits 3. The apparatus further comprises a modulator 14 for generating a modulated signal by subjecting the 128QAM transmission frame generated by the transmission frame constructing circuit 13 to M-ary quadrature amplitude modulation (128QAM) and outputting the modulated signal to a communication channel 15 for transmission.

The apparatus further comprises a demodulator 16 for subjecting a modulated signal received via the communication channel 15 and having noise superimposed thereon to M-ary quadrature amplitude demodulation (128QAM demodulation), and outputting a received frame (received QAM symbols of an arrangement of 7 bits per symbol), a frame synchronization circuit 17 for establishing frame synchronization by referring to extra bits added for transmission control in the received frame output from the demodulator 16, and outputting a synchronization signal to an RS frame decomposing circuit 18 and an RS decoding circuit 19. The apparatus further comprises an RS frame decomposing circuit 18 for decomposing, in synchronization with the synchronization signal output from the frame synchronization circuit 17, the received frame output from the demodulator 16 and outputting received bits corresponding to the RS information bits 1 and the RS parity bits 2, and an RS decoding circuit 19 for identifying, in synchronization with the synchronizing signal output from the frame synchronization circuit 17, the RS information bits 1 by estimation based on the received bits output from the RS frame decomposing circuit 18.

A description will now be given of the operation according to the apparatus of the related art.

It is assumed that 128QAM is used as M-ary quadrature amplitude modulation and multidimensional block codes such as RS codes are used for error correction. In this example, information bits are arranged as shown in FIG. 5A by assigning 7 information bits to a symbol so as to produce the RS information bits 1.

The RS information bits 1 are supplied to the delay buffer 11 for temporary storage and also supplied to the RS encoding circuit 12 for RS encoding.

The RS encoding circuit 12 subjects the RS information bits 1 to RS encoding so as to produce the RS parity bits 2 of an arrangement of 7 bits per symbol as shown in FIG. 5A.

When the RS encoding circuit 12 generates the RS parity bits 2, the transmission frame constructing circuit 13 combines the RS information bits 1 stored in the delay buffer 11 and the RS parity bits 2 so as to produce the RS encoded bits. As shown in FIG. 5A, each series of RS encoded bits has a code length of 127 symbols, an information length of 119 symbols and a parity length of 8 symbols.

The transmission constructing circuit 13 forms the 128QAM transmission frame by adding extra bits for transmission control including the RS frame synchronization bits 3, to the RS encoded bits, as shown in FIG. 5B.

When the transmission frame constructing circuit 13 forms the 128QAM transmission frame, the modulator 14 subjects the 128QAM transmission frame to modulation according to 128QAM so as to generate a modulated signal and outputs the modulated signal to the communication channel 15 for transmission. The demodulator 16 receives from the communication channel 15 the modulated signal on which noise is superimposed in the communication channel 15. The demodulator 16 subjects the received signal to demodulation according to 128QAM and outputs a received frame (received QAM symbols of an arrangement of 7 bits per symbol).

When the demodulator 16 outputs the received frame, the frame synchronization circuit 17 establishes frame synchronization by referring to the extra bits added for transmission control in the received frame and outputs a synchronization signal to the RS frame decomposing circuit 18 and the RS decoding circuit 19.

The RS frame decomposing circuit 18 decomposes, in synchronization with the synchronization signal output from the frame synchronization circuit 17, the received frame output from the demodulator 16 and outputs received bits corresponding to the RS information bits 1 and the RS parity bits 2.

The RS decoding circuit 19 identifies, in synchronization with the synchronizing signal output from the frame synchronization circuit 17, the RS information bits 1 by estimation based on the received bits output from the RS frame decomposing circuit 18.

As described above, it is possible for the transmission apparatus according to the related art to identify by estimation the RS information bits 1 input on the transmitting end on the condition that the number of bits per symbol of the RS code is equal to the number of bits per QAM symbol. Accordingly, a restriction is imposed on the selection of RS codes.

Japanese Laid-Open Patent Application No. 2000-261511 discloses a transmission apparatus in which disadvantages resulting from the restriction imposed on the selection of RS codes is eliminated.

FIG. 6 shows a construction of a transmission apparatus according to the related art disclosed in Japanese Laid-Open Patent Application No. 200-261511. FIG. 7A shows an RS encoded frame produced as a result of RS encoding over a Galois field of GF (2⁸). FIG. 7B shows a transmission frame used for transmission of the RS encoded frame using 128QAM.

Referring to FIGS. 7A and 7B, information bits are arranged by assigning 8 bits to a symbol so as to produce RS information bits 21. RS parity bits 22 are generated by subjecting the RS information bits 21 to RS encoding. The 128QAM transmission frame comprises frame synchronization bits 23 and RS encoded bits 24 produced by subjecting the RS information bits of an arrangement of 8 bits per symbol to rate conversion into QAM symbols of an arrangement of 7 bits per symbol.

Referring to FIG. 6, the transmission apparatus comprises a delay buffer 31 for temporarily storing the RS information bits 21, an RS encoding circuit 32 for subjecting the RS information bits 21 to RS encoding so as to generate the RS parity bits 22 of an arrangement of 8 bits per symbol, a transmission frame constructing circuit 33 for forming RS encoded bits by combining the RS information bits 21 and the RS parity bits 22, a rate conversion circuit 34 for subjecting the RS information bits of an arrangement of 8 bits per symbol to rate conversion into QAM symbols of an arrangement of 7 bits per symbol, a synchronization bit adding circuit 35 for adding extra bits for transmission control including the RS frame synchronization bits 23 to the RS encoded bits output from the rate conversion circuit 34 so as to produce a 128QAM transmission frame. The apparatus further comprises a modulator 36 for generating a modulated signal by subjecting the 128QAM transmission frame generated by the synchronization bit adding circuit 35 to M-ary quadrature amplitude modulation (128QAM) and outputting the modulated signal to a communication channel 37 for transmission.

A demodulator 38 receives via the communication channel 37 a modulated signal on which noise is superimposed and outputs a received frame (received QAM symbols of an arrangement of 7 bits per symbol) by subjecting the received signal to M-ary quadrature amplitude modulation (128QAM). A frame synchronization circuit 39 establishes frame synchronization by referring to extra bits added for transmission control in the received frame output from the demodulator 38 and outputs a synchronization signal to an inverse rate conversion circuit 40, an RS frame decomposing circuit 41 and an RS decoding circuit 42. The inverse rate conversion circuit 40 subjects, in synchronization with the synchronization signal output from the frame synchronization circuit 39, the QAM symbols of an arrangement of 7 bits per symbol to inverse rate conversion into RS symbols of an arrangement of 8 bits per symbol. The RS frame decomposing circuit 41 decomposes, in synchronization with the synchronization signal output from the frame synchronization circuit 39, the received frame output from the demodulator 38 and outputs received bits corresponding to the RS information bits 21 and the RS parity bits 22. The RS decoding circuit 42 identifies, in synchronization with the synchronizing signal output from the frame synchronization circuit 39, the RS information bits 21 by estimation based on the received bits output from the RS frame decomposing circuit 41.

A description will now be given of the operation of the apparatus according to Japanese Laid-Open Patent Application No. 200-261511.

In this example, information bits are arranged as shown in FIG. 7A by assigning 8 information bits to a symbol so as to produce the RS information bits 21 for transmission.

The RS information bits 21 are supplied to the delay buffer 31 for temporary storage and also supplied to the RS encoding circuit 32 for RS encoding.

The RS encoding circuit 32 subjects the RS information bits 21 to RS encoding so as to produce the RS parity bits 22 of an arrangement of 8 bits per symbol as shown in FIG. 7A.

When the RS encoding circuit 32 generates the RS parity bits 22, the transmission frame constructing circuit 33 combines the RS information bits 21 stored in the delay buffer 31 and the RS parity bits 22 so as to produce the RS encoded bits. As shown in FIG. 7A, each series of the RS encoded bits has a code length of 255 symbols, an information length of 239 symbols and a parity length of 16 symbols.

The rate conversion circuit 34 receiving the RS encoded bits from the transmission frame constructing circuit 33 subjects the RS symbols of an arrangement of 8 bits per symbol to rate conversion into QAM symbols of an arrangement of 7 bits per symbol so as to output the RS encoded bits 24 as shown in FIG. 7B.

The synchronization bit adding circuit 35 forms the 128QAM transmission frame by adding, as shown in FIG. 7B, extra bits for transmission control including the RS frame synchronization bits 23, to the RS encoded bits 24 output from the rate conversion circuit 34.

When the synchronization bit adding circuit 35 forms the 128QAM transmission frame, the modulator 36 generates a modulates signal by subjecting the 128QAM transmission frame to 128QAM and outputs the modulated signal to the communication channel 37 for transmission.

The demodulator 38 receives from the communication channel 37 the modulated signal on which noise is superimposed in the communication channel 37. The demodulator 38 then subjects the received signal to demodulation according to 128QAM and outputs a received frame (received QAM symbols of an arrangement of 7 bits per symbol).

When the demodulator 38 outputs the received frame, the frame synchronization circuit 39 establishes frame synchronization by referring to the extra bits added for transmission control in the received frame and outputs a synchronization signal to the inverse rate conversion circuit 40, the RS frame decomposing circuit 41 and the RS decoding circuit 42.

The inverse rate conversion circuit 40 subjects the QAM symbols of an arrangement of 7 bits per symbol to rate conversion into RS symbols of an arrangement of 8 bits per symbol, in synchronization with the frame synchronization signal output from the frame synchronization circuit 39.

The RS frame decomposing circuit 41 decomposes, in synchronization with the synchronization signal output from the frame synchronization circuit 39, the received frame subjected to rate conversion by the rate conversion circuit 40 and outputs received bits corresponding to the RS information bits 21 and the RS parity bits 22.

The RS decoding circuit 42 identifies, in synchronization with the synchronizing signal output from the frame synchronization circuit 39, the RS information bits 21 by estimation based on the received bits output from the RS frame decomposing circuit 41.

While the related-art transmission apparatus constructed as described above is capable of eliminating the disadvantage of a restriction being imposed on the selection of RS codes, there is a disadvantage in that it is necessary to provide the rate conversion circuit 34 and the inverse rate conversion circuit 40, which are relatively complex, for matching of the number of bits per RS symbol with the number of bits per QAM symbol.

### SUMMARY OF THE INVENTION

Accordingly, a general object of the present invention is to provide a transmission apparatus and a transmission method in which the aforementioned disadvantage is eliminated.

Another and more specific object is to provide a transmission apparatus and a transmission method in which simplified rate conversion is performed without providing a relatively complex rate conversion circuit for matching of the number of bits per symbol, even when the number of bits per RS symbol is greater than the number of bits per QAM symbol.

The aforementioned objects can be achieved by a transmission apparatus or a transmission method comprising: encoding for error correction bits for information symbols in which information bits are assigned to low-order bits and dummy bits are assigned to high-order bits, so as to generate bits for parity symbols such that the number of bits per information symbol is equal to the number of bits per parity symbol, and subjects the high-order bits for parity symbols to symbol conversion; constructing a transmission frame by combining low-order bits for information symbols, low-order bits for parity symbols, bits subjected to symbol conversion by the encoding means and extra bits for transmission control; subjecting the transmission frame constructed by the frame constructing means to M-ary quadrature amplitude modulation and outputting a resultant modulated signal to a communication channel; subjecting the modulated signal received via the communication channel to M-ary quadrature amplitude demodulation and outputting a resultant received frame; establishing frame synchronization by referring to the extra bits included in the received frame output from the receiving means and decomposing the received frame into bits corresponding to information symbols and bits corresponding to parity symbols; and subjecting the bits corresponding to parity symbols and output from the frame decomposing means to inverse symbol conversion and identifying the bits for information symbols by estimation based on the bits subjected to inverse symbol conversion and the bits corresponding to information symbols and output from the frame decomposing means.

The aforementioned objects can also be achieved by a transmission apparatus or a transmission method comprising: encoding for error correction bits for information symbols in which information bits and extra bits for transmission control are assigned to low-order bits and dummy bits are assigned to high-order bits, so as to generate bits for parity symbols such that the number of bits per information symbol is equal to the number of bits per parity symbol, and subjects the high-order bits for parity symbols to symbol conversion; constructing a transmission frame by combining low-order bits for information symbols, low-order bits for parity symbols and bits subjected to symbol conversion by the encoding means; subjecting the transmission frame constructed by the frame constructing means to M-ary quadrature amplitude modulation and outputting a resultant modulated signal to a communication channel; subjecting the modulated signal received via the communication channel to M-ary quadrature amplitude demodulation and outputting a resultant received frame; establishing frame synchronization by referring to the extra bits included in the received frame output from the receiving means and decomposing the received frame into bits corresponding to information symbols and bits corresponding to parity symbols; and subjecting the bits corresponding to parity symbols and output from the frame decomposing means to inverse symbol conversion and identifying the bits for information symbols by estimation based on the bits subjected to inverse symbol conversion and the bits corresponding to information symbols and output from the frame decomposing means.

Accordingly, even when the number of bits per RS symbol is greater than the number of bits per QAM symbol, it is not necessary to provide a complex circuit such as a rate conversion circuit for matching of the number of bits. As a result, a simplified form of rate conversion is performed.

By ensuring that, when there is a free area in an area for storing the extra bits, the free space in a subsequent transmission frame is allocated to the bits subjected by said encoding means to symbol conversion, the number of QAM symbols transmitted is reduced.

By determining that a decoding error occurs when high-order bits of the bits for information symbols identified by estimation are not identical to the dummy bits, decoding errors are properly detected.

### BRIEF DESCRIPTION OF THE DRAWINGS

Other objects and further features of the present invention will be apparent from the following detailed description when read in conjunction with the accompanying drawings, in which:

FIG. 1 shows a construction of a transmission apparatus according to a first embodiment of the present invention;

FIGS. 2A and 2B show a construction of frames transmitted in a scheme in which M-ary quadrature amplitude modulation is used for modulation and the Reed-Solomon code, a multidimensional block error correction code, is used for error correction;

FIG. 3 is a flowchart showing a transmission method according to the first embodiment;

FIG. 4 shows a construction of a transmission apparatus according to the related art;

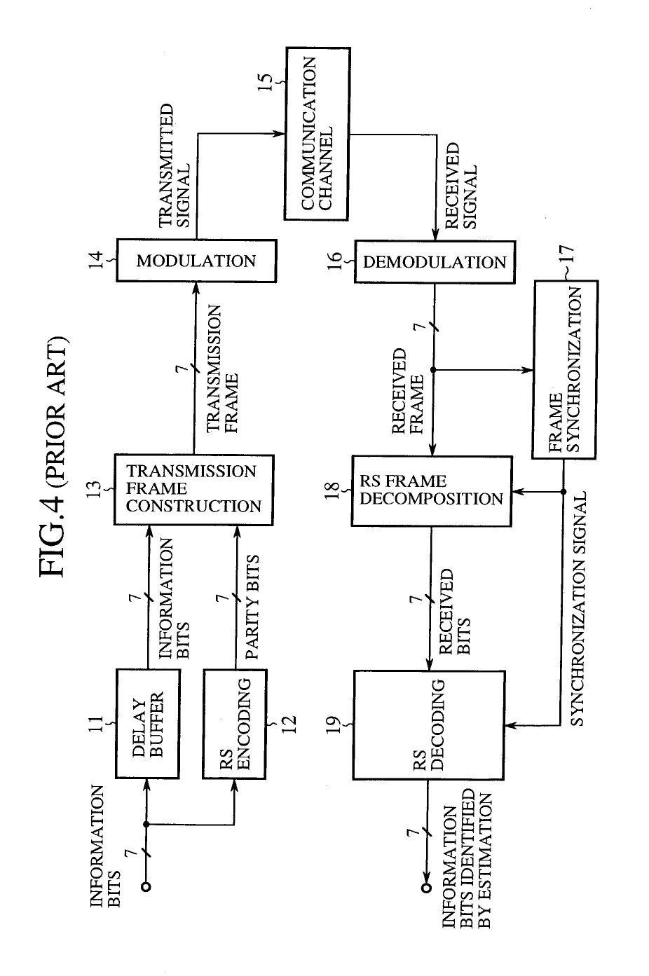

FIGS. 5A and 5B show a construction of frames transmitted in a scheme in which M-ary quadrature amplitude modulation is used for modulation and the Reed-Solomon code, a multidimensional block error correction code, is used for error correction;

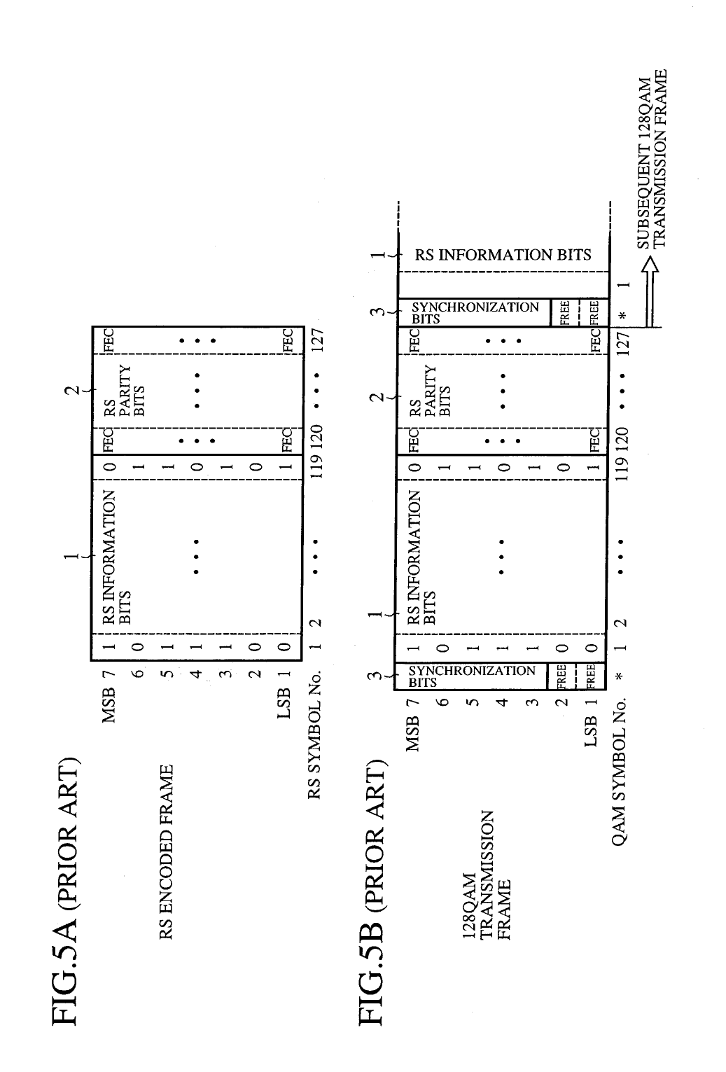

FIG. 6 shows a construction of a transmission apparatus according to the related art; and

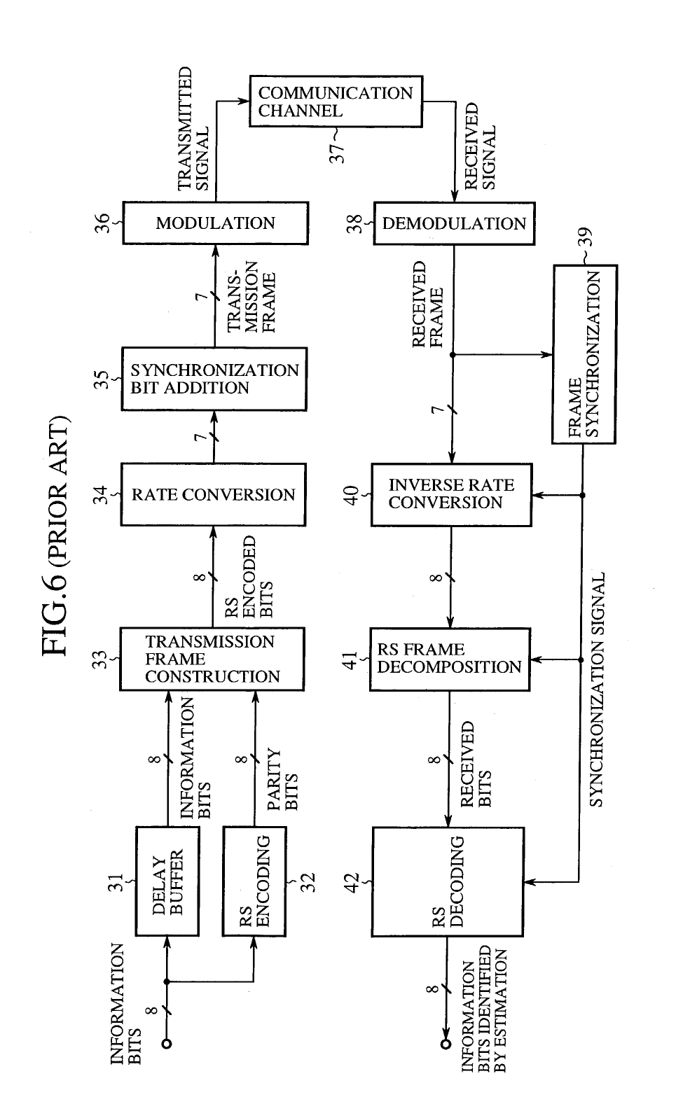

FIGS. 7A and 7B show a construction of frames transmitted in a scheme in which M-ary quadrature amplitude modulation is used for modulation and the Reed-Solomon code, a multidimensional block error correction code, is used for error correction.

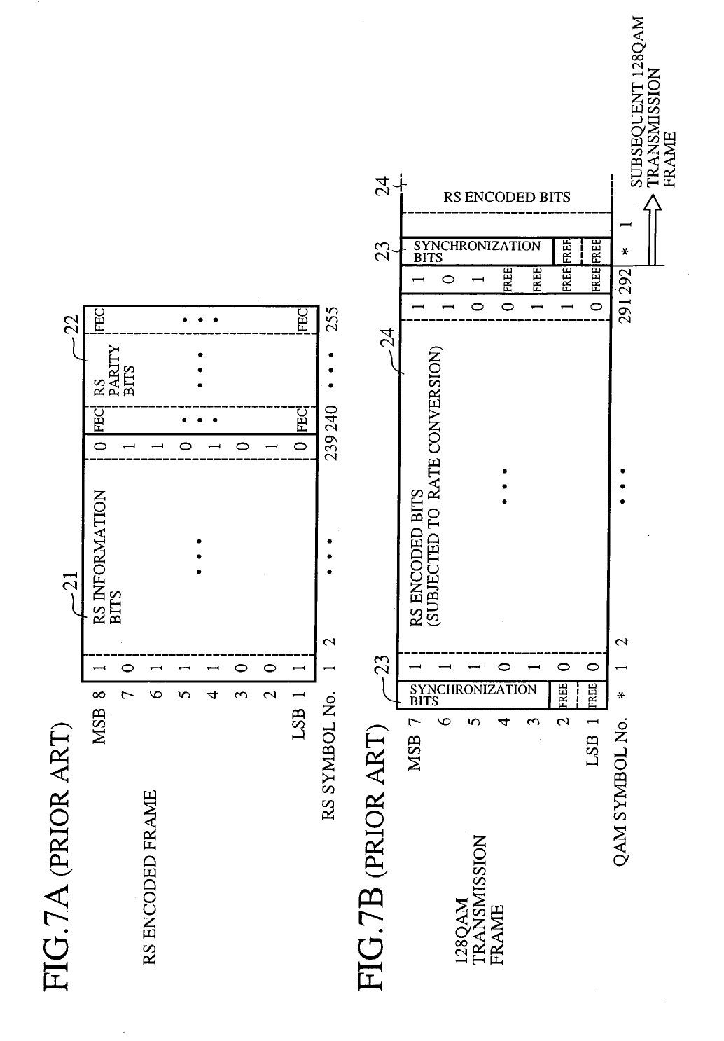

### DETAILED DESCRIPTION OF THE PREFERRED EMBODIMENTS

First Embodiment

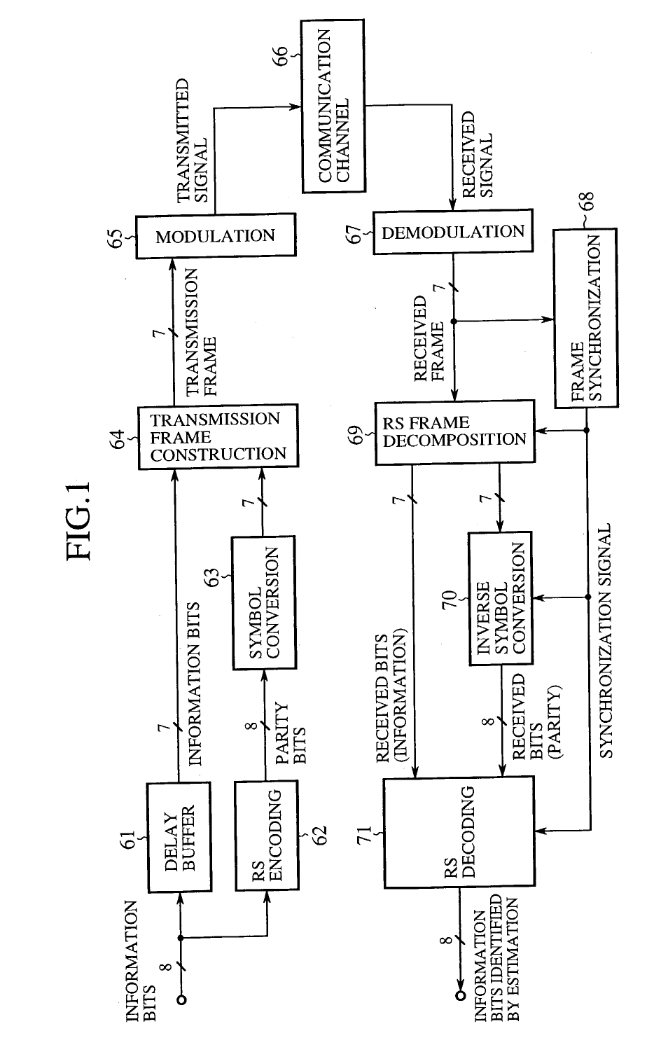

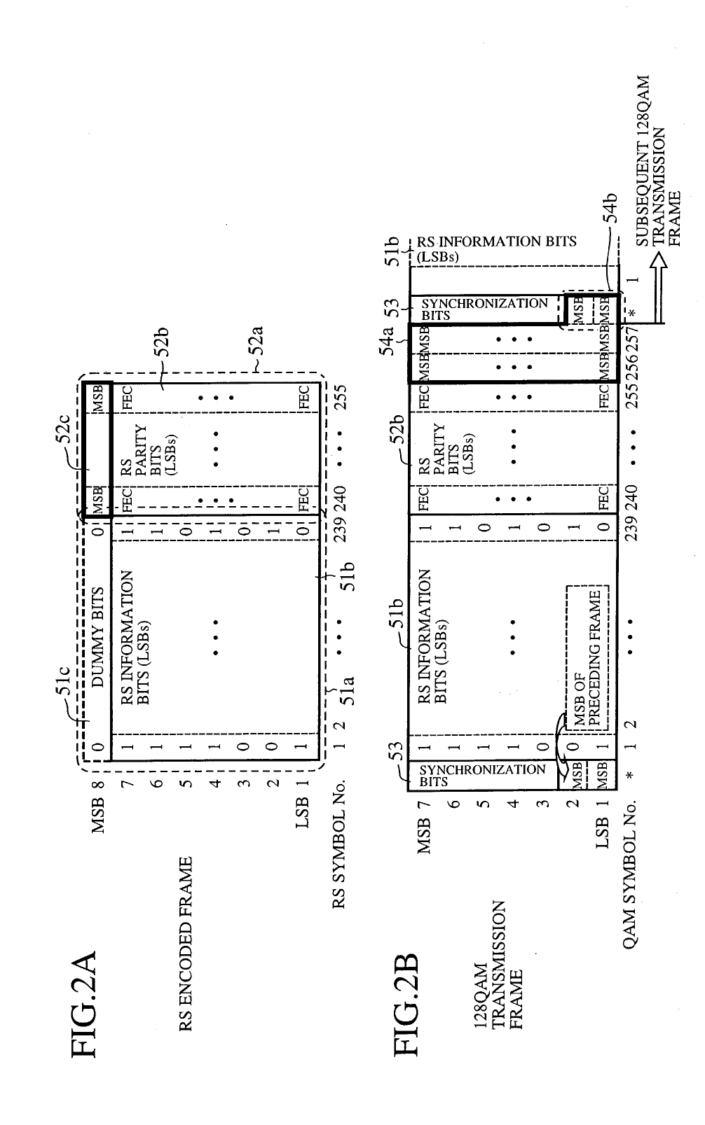

FIG. 1 shows a construction of a transmission apparatus according to the first embodiment. FIGS. 2A and 2B show a construction of frames transmitted in a scheme in which M-ary quadrature amplitude modulation is used for modulation and the Reed-Solomon code, a multidimensional block error correction code, is used for error correction. FIG. 2A shows an RS encoded frame RS encoded over a Galois field of GF(2⁸). FIG. 2B shows a transmission frame used when the RS encoded frame is transmitted using 128QAM.

Referring to FIG. 2A, the RS encoded frame according to the first embodiment comprises RS information symbols 51a (hereinafter, referred to as RS information bits) in which information bits are assigned to low-order bits and dummy bits are assigned to high-order bits. More particularly, the RS information bits 51a comprises dummy bits 51c and low-order bits 51b for RS information symbols arranged by assigning 7 information bits to a symbol. RS parity symbols 52a (hereinafter, referred to as RS parity bits) are generated by RS encoding the RS information bits 51a. The RS parity bits 52a comprises low-order bits 52b for RS parity symbols and high-order bits 52c for RS parity symbols. Referring to FIG. 2B, the 128QAM transmission frame comprises RS frame synchronization bits (extra bits added for transmission control) 53 for RS frame synchronization, bits 54 produced by converting the high-order bits for RS parity symbols into QAM symbols, and high-order bits 54b for RS parity symbols, a free area in an area for storing the extra bits added for control of a subsequent transmission frame being allocated to the bits 54b.

The apparatus according to the first embodiment comprises a delay buffer 61 for temporarily storing the RS information bits 51a, an RS encoding circuit 62 for RS encoding the RS information bits 51a so as to generate the RS parity bits 52a of an arrangement of 8 bits per symbol, and a symbol conversion circuit 63 using the low-order bits 52b for RS parity symbols as QAM symbol bits 52b and construct QAM symbols 54a by ordering the high-order bits 52c for RS parity symbols in an arrangement of 7 bits per symbol.

The RS encoding circuit 62 and the symbol conversion circuit 63 constitute encoding means.

A transmission frame constructing circuit (frame constructing means) constructs a 128QAM transmission frame by combining the low-order bits 51b for RS information symbols stored in the delay buffer 61, the low-order bits 52b and the QAM symbols 54a output from the symbol conversion circuit 63, and the extra bits added for transmission control including the RS frame synchronization bits 53. A modulator 65 (transmitting means) generates a modulated signal by subjecting the 128QAM transmission frame constructed by the transmission frame constructing circuit 64 to M-ary quadrature amplitude modulation (128QAM) and outputs the modulated signal to a communication channel for transmission.

A demodulator (receiving means) 67 receives the modulated signal on which noise is superimposed and outputs a received frame (received QAM symbols of an arrangement of 7 bits per symbol) by subjecting the received signal to M-ary quadrature amplitude modulation (128QAM). An RS frame decomposing circuit 68 establishes frame synchronization by referring to the extra bits added for transmission control in the received frame output from the demodulator 67 and outputs a synchronization signal to an RS frame decomposing circuit 69, an inverse symbol conversion circuit 70 and an RS decoding circuit 71. The RS frame decomposing circuit 69 decomposes the received frame output from the demodulator 67 in synchronization with the synchronization signal output from the frame synchronization circuit 68 so as to output received bits corresponding to the low-order bits 51b for RS information symbols and received bits corresponding to the RS parity bits 52a and 54a.

An inverse symbol conversion circuit 70 combines, in synchronization with the synchronization signal output from the frame synchronization circuit 68, the received bits corresponding to the RS parity bits 52b and 54a output from the RS frame decomposing circuit 69, so as to produce RS symbols of an arrangement of 8 bits per symbol by inverse conversion. An RS decoding circuit 71 identifies, in synchronization with the synchronization signal output from the frame synchronization circuit 68, the RS information bits 51a by estimation based on the received bits corresponding to the low-order bits 51b for RS information symbols and output from the RS frame decomposing circuit 69, and based on the received bits output from the inverse symbol circuit 70.

The inverse symbol conversion circuit 70 and the RS decoding circuit 71 constitute decoding means.

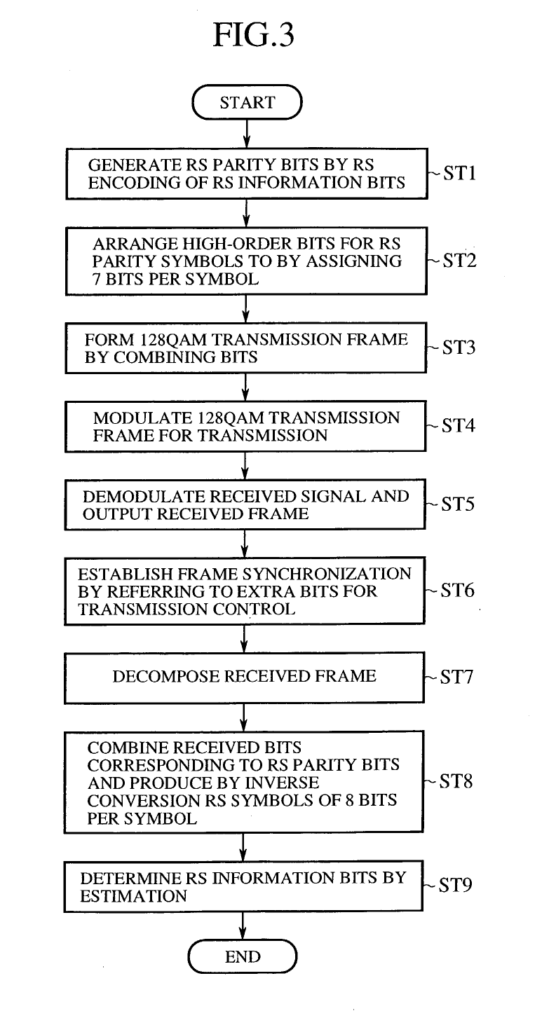

FIG. 3 is a flowchart showing a transmission method according to the first embodiment.

A description will now be given of the operation according to the first embodiment.

It is assumed that 128QAM is used as M-ary quadrature amplitude modulation and RS codes over a Galois field of GF(2⁸) are used for error correction. Application of the first embodiment is not limited to the particular transmission scheme mentioned above.

The RS information bits 51 are supplied to the transmission apparatus. The RS information bits 51 comprises the dummy bits 51c and the low-order bits 51b for RS information symbols produced by arranging information bits into an arrangement of 7 bits per symbol.

The dummy bits may be of any predetermined pattern. For example, all 0s may be used as the dummy bits.

The input RS information bits 51a are then supplied to the delay buffer 61 for temporary storage. The RS information bits 51a are also supplied to the RS encoding circuit 62 for RS encoding.

The RS encoding circuit 62 subjects the RS information bits 51a to RS encoding so as to generate the RS parity bits 52a of an arrangement of 8 bits per symbol as shown in FIG. 2A (step ST1).

Each series of the bits comprising the RS information bits 51a and the RS parity bits 52a has a code length of 255 symbols, an information length of 239 symbols and a parity length of 16 symbols.

When the RS encoding circuit 62 generates the RS parity bits 52a of an arrangement of 8 bits per symbol, the symbol conversion circuit 63 outputs the low-order bits 52b for RS parity symbols to the transmission constructing circuit 64 as the QAM symbols 52b. The symbol conversion circuit 63 also arranges the high-order bits 52c for RS parity symbols into an arrangement of 7 bits per symbol and outputs the resultant bits to the transmission frame constructing circuit 64 as the QAM symbol bits 54a (step ST2).

If remainders are produced as a result of 8-bit to 7-bit conversion, i.e., if any remainder bits are produced as a result of the arrangement of the high-order bits 52c for RS parity symbols, the remainder bits are output to the transmission frame constructing circuit 64.

When the symbol conversion circuit 63 outputs the bits 52b and the bits 54a, the transmission frame constructing circuit 64 combines the low-order bits 51b for RS information symbols stored in the delay buffer 61, the bits 52b output from the symbol conversion circuit 63 and the bits 54a so as to produce the RS encoded bits.

As shown in FIG. 2B, the transmission frame constructing circuit 64 forms the 128QAM transmission frame by adding the extra bits for transmission control including the RS frame synchronization bits 53 to the RS encoded bits (step ST3).

When there is a free area in an area for storage of the extra bits added in a subsequent transmission frame for transmission control, the remainder bits output from the symbol conversion circuit 63 are embedded as the bits 54b in the free area, as shown in FIG. 2B, in order to reduce the number of QAM symbols transmitted.

When the transmission frame constructing circuit 64 forms the 128QAM transmission frame, the modulator 65 generates a modulated signal by subjecting the transmission frame to 128QAM and outputs the modulates signal to the communication channel for transmission (step ST4).

The demodulator 67 receives from the communication channel 66 the modulated signal on which noise is superimposed in the communication channel 66. The demodulator 67 then subjects the received signal to demodulation according to 128QAM and outputs a received frame (received QAM symbols of an arrangement of 7 bits per symbol) (step ST5).

When the demodulator 67 outputs the received frame, the frame synchronization circuit 68 establishes frame synchronization by referring to the extra bits added for transmission control in the received frame and outputs a synchronization signal to the RS frame decomposing circuit 69, the inverse rate conversion circuit 70, and the RS decoding circuit 71 (step ST6).

The RS frame decomposing circuit 69 decomposes, in synchronization with the synchronization signal output from the frame synchronization circuit 68, the received frame output from the demodulator 67 and outputs received bits corresponding to the low-order bits 51b for RS information symbols and the bits 52b and 54a for RS parity (step ST7).

The inverse symbol conversion circuit 70, receiving the received bits corresponding to the bits 52b and 54a for RS parity from the RS frame decomposing circuit 69, combines the received bits corresponding to the bits 52b for RS parity and the received bits corresponding to the bits 54a for RS parity, in synchronization with the synchronization signal output from the frame synchronization circuit 68, so as to produce by inverse conversion RS symbols of an arrangement of 8 bits per symbol (step ST8).

The RS decoding circuit 71 identifies, in synchronization with the synchronizing signal output from the frame synchronization circuit 68, the RS information bits 51a by estimation based on the received bits corresponding to the low-order bits 51b for RS information symbols and output from the RS frame decomposing circuit 69, and based on the received bits output from the inverse symbol conversion circuit 70 (step ST9).

The dummy bits in the high-order portion of the RS information bits 51a are assigned to respective positions assuming that the dummy bits of the predetermined pattern are received.

As described above, according to the first embodiment, there is provided encoding means for encoding bits for information symbols, in which information bits are assigned to low-order bits and dummy bits are assigned to high-order bits. The encoding means generates parity bits such that the number of information bits per symbol is equal to the number of parity bits per symbol. The encoding means further subjects the high-order parity bits to symbol conversion. The frame constructing means combines the low-order bits for information symbols, the low-order parity bits, the bits subjected to symbol conversion by the encoding means and the extra bits added for transmission control, so as to construct the transmission frame. Accordingly, even when the number of bits per RS symbol is greater than the number of bits per QAM symbol, it is not necessary to provide a complex circuit such as a rate conversion circuit for matching of the number of bits. As a result, a simplified form of rate conversion is performed.

When the number of bits per RS symbol is greater than the number of bits per QAM symbol, bits that would remain (left out) as a result of symbol conversion of bits corresponding to RS information symbols are not transmitted as dummy bits. Only those bits corresponding to RS parity symbols are transmitted as separate QAM symbols. Accordingly, transmission is possible using a simplified form of rate conversion in which only those bits for RS parity symbols are subjected to symbol conversion.

Second Embodiment

According to the first embodiment, the RS encoding circuit 62 RS encodes the RS information bits 51a. Subsequently, the transmission frame constructing circuit 64 forms a 128QAM transmission frame by adding to the RS encoded bits the extra bits for transmission control including the RS frame synchronization bits 53. Alternatively, the RS encoding circuit 62 may include the extra bits for transmission control including the RS frame synchronization bits 53 in the low-order bits 51b for RS information symbols before RS encoding the resultant RS information bits 51a.

The low-order bits 51b for RS information symbols remain unchanged after the RS encoding so that no problem is presented by adding the extra bits for transmission control prior to the RS encoding. A disadvantage with this is that the efficiency of transmission suffers by adding the extra bits.

Third Embodiment

When the high-order bits of the RS information bits 51a identified by estimation have a pattern different from the predetermined pattern of dummy bits, the RS decoding circuit 71 may determine that a decoding error occurs.

The present invention is not limited to the above-described embodiments, and variations and modifications may be made without departing from the scope of the present invention.

What is claimed is

1. A transmission apparatus comprising:
encoding means for encoding for error correction bits for information symbols in which information bits are assigned to low-order bits and dummy bits are assigned to high-order bits, so as to generate bits for parity symbols such that the number of bits per information symbol is equal to the number of bits per parity symbol, and subjects the high-order bits for parity symbols to symbol conversion;
frame constructing means for constructing a transmission frame by combining low-order bits for information symbols, low-order bits for parity symbols, bits subjected to symbol conversion by said encoding means and extra bits for transmission control;
transmitting means for subjecting the transmission frame constructed by said frame constructing means to M-ary quadrature amplitude modulation and outputting a resultant modulated signal to a communication channel;
receiving means for subjecting the modulated signal received via the communication channel to Mary quadrature amplitude demodulation and outputting a resultant received frame;
frame decomposing means for establishing frame synchronization by referring to the extra bits included in the received frame output from said receiving means and decomposing the received frame into bits corresponding to information symbols and bits corresponding to parity symbols; and
decoding means for subjecting the bits corresponding to parity symbols and output from said frame decomposing means to inverse symbol conversion and identifying the bits for information symbols by estimation based on the bits subjected to inverse symbol conversion and the bits corresponding to information symbols and output from said frame decomposing means.

2. A transmission apparatus comprising:
encoding means for encoding for error correction bits for information symbols in which information bits and extra bits for transmission control are assigned to low-order bits and dummy bits are assigned to high-order bits, so as to generate bits for parity symbols such that the number of bits per information symbol is equal to the number of bits per parity symbol, and subjects the high-order bits for parity symbols to symbol conversion;
frame constructing means for constructing a transmission frame by combining low-order bits for information symbols, low-order bits for parity symbols and bits subjected to symbol conversion by said encoding means;
transmitting means for subjecting the transmission frame constructed by said frame constructing means to M-ary quadrature amplitude modulation and outputting a resultant modulated signal to a communication channel;
receiving means for subjecting the modulated signal received via the communication channel to M-ary quadrature amplitude demodulation and outputting a resultant received frame;
frame decomposing means for establishing frame synchronization by referring to the extra bits included in the received frame output from said receiving means and decomposing the received frame into bits corresponding to information symbols and bits corresponding to parity symbols; and
decoding means for subjecting the bits corresponding to parity symbols and output from said frame decomposing means to inverse symbol conversion and identifying the bits for information symbols by estimation based on the bits subjected to inverse symbol conversion and the bits corresponding to information symbols and output from said frame decomposing means.

3. The transmission apparatus according to claim 1, wherein, when there is a free area in an area for storing the extra bits, said frame constructing means allocates the free space in a subsequent transmission frame to the bits subjected by said encoding means to symbol conversion.

4. The transmission apparatus according to claim 2, wherein, when there is a free area in an area for storing the extra bits, said frame constructing means allocates the free space in a subsequent transmission frame to the bits subjected by said encoding means to symbol conversion.

5. The transmission apparatus according to claim 1, wherein said decoding means determines that a decoding error occurs when high-order bits of the bits for information symbols identified by estimation are not identical to the dummy bits.

6. The transmission apparatus according to claim 2, wherein said decoding means determines that a decoding error occurs when high-order bits of the bits for information symbols identified by estimation are not identical to the dummy bits.

7. A transmission method comprising the steps of:
encoding for error correction bits for information symbols in which information bits are assigned to low-order bits and dummy bits are assigned to high-order bits, so as to generate bits for parity symbols such that the number of bits per information symbol is equal to the number of bits per parity symbol, and subjecting the high-order bits for parity symbols to symbol conversion;
constructing a transmission frame by combining low-order bits for information symbols, low-order bits for parity symbols, bits subjected to symbol conversion by said encoding means and extra bits for transmission control;
subjecting the transmission frame to M-ary quadrature amplitude modulation and outputting a resultant modulated signal to a communication channel;
subjecting the modulated signal received via the communication channel to M-ary quadrature amplitude demodulation and outputting a resultant received frame;
establishing frame synchronization by referring to the extra bits included-in the received frame and decomposing the received frame into bits corresponding to information symbols and bits corresponding to parity symbols; and
subjecting the bits corresponding to parity symbols to inverse symbol conversion and identifying-the bits for information symbols by estimation based on the bits subjected to inverse symbol conversion and the bits corresponding to information symbols.

8. A transmission method comprising the steps of:
encoding for error correction bits for information symbols in which information bits and extra bits for transmission control are assigned to low-order bits and dummy bits are assigned to high-order bits, so as to generate bits for parity symbols such that the number of bits per information symbol is equal to the number of bits per parity symbol, and subjects the high-order bits for parity symbols to symbol conversion;
constructing a transmission frame by combining low-order bits for information symbols, low-order bits for parity symbols and bits subjected to symbol conversion in;
subjecting the transmission frame to M-ary quadrature amplitude modulation and outputting a resultant modulated signal to a communication channel;
subjecting the modulated signal received via the communication channel to M-ary quadrature amplitude demodulation and outputting a resultant received frame;
establishing frame synchronization by referring to the extra bits included in the received frame and decomposing the received frame into bits corresponding to information symbols and bits corresponding to parity symbols; and
subjecting the bits corresponding to parity symbols to inverse symbol conversion and identifying the bits for information symbols by estimation based on the bits subjected to inverse symbol conversion and the bits corresponding to information symbols.

9. The transmission method according to claim 7, wherein, when there is a free area in an area for storing the extra bits, the free space in a subsequent transmission frame is allocated to the bits subjected by said encoding means to symbol conversion.

10. The transmission method according to claim 8, wherein, when there is a free area in an area for storing the extra bits, the free space in a subsequent transmission frame is allocated to the bits subjected by said encoding means to symbol conversion.

11. The transmission method according to claim 7, wherein it is determined that a decoding error occurs when high-order bits of the bits for information symbols identified by estimation are not identical to the dummy bits.

12. The transmission method according to claim 8, wherein it is determined that a decoding error occurs when high-order bits of the bits for information symbols identified by estimation are not identical to the dummy bits.
